(19) United States
(12) Patent Application Publication
(10) Pub. No.: US 2026/0255879 A1
(43) Pub. Date: Aug. 27, 2026

(54) METHOD FOR MANUFACTURING A STRUCTURE COMPRISING A BARRIER LAYER TO PREVENT DIFFUSION OF ATOMIC SPECIES

(71) Applicants: Soitec, BERNIN (FR); Commissariat à l'Energie Atomique et aux Energies Alternatives, Paris (FR)

(72) Inventors: Odile Mourey, BERNIN (FR); Luciana Capello, BERNIN (FR); Isabelle Huyet, BERNIN (FR); Sebastien Kerdiles, Grenoble Cedex 9 (FR); Soazig Leforestier, Grenoble Cedex 9 (FR)

(21) Appl. No.: 18/875,758

(22) PCT Filed: May 31, 2023
(86) PCT No.: PCT/EP2023/064571

§ 371 Date: Dec. 17, 2024

(30) Foreign Application Priority Data
Jun. 29, 2022 (FR) FR2206501

(51) Int. Cl. H10N 30/079; H10N 30/00; H10N 30/073; H10N 30/085

(52) U.S. Cl. CPC H10N 30/079; H10N 30/073; H10N 30/085; H10N 30/708

(57) ABSTRACT

A structure comprises a support including an electric charge-trapping layer on the surface of a base substrate. The structure further comprises a thin layer of a lithium-based material on the support. The structure comprises an interlayer dielectric layer arranged between, and in contact with, the support and the thin layer. The interlayer dielectric layer comprises a first dielectric layer arranged on, and in contact with, the charge-trapping layer, a silicon nitride barrier layer arranged on, and in contact with, the first dielectric layer and a second dielectric layer arranged on, and in contact with, the silicon nitride barrier layer.

### CROSS-REFERENCE TO RELATED APPLICATIONS

This application is a national phase entry under 35 U.S.C. § 371 of International Patent Application PCT/EP2023/064571, filed May 31, 2023, designating the United States of America and published as International Patent Publication WO 2024/002608 A1 on Jan. 4, 2024, which claims the benefit under Article 8 of the Patent Cooperation Treaty of French Patent Application Serial No. FR 2206501, filed Jun. 29, 2022.

### TECHNICAL FIELD

The present disclosure relates to a method for manufacturing a structure comprising a thin layer transferred onto a support provided with a charge-trapping layer. The present disclosure is particularly useful in the fields of microelectronics, microsystems, photonics, etc.

### BACKGROUND

Document WO2021008742 points out that it is often advantageous to provide an electric charge-trapping layer (more concisely referred to as a “trapping layer” in the remainder of this description) in the support of a structure formed by a thin layer transferred, via a dielectric layer, onto this support. The manufacture of this type of structure is disclosed, for example, in documents FR2860341, FR2933233, FR2953640, US2015115480, U.S. Pat. No. 7,268,060 and U.S. Pat. No. 6,544,656. In particular, it can be used to shape electronic or electroacoustic components in the field of radio frequency (RF) signals. US20180114720A1 and US20180158721A1 also propose “semiconductor-on-insulator” structures comprising a trapping layer.

The thin film, often monocrystalline, can be semiconducting (e.g., silicon-to form an SOI, or “silicon on insulator,” structure) or insulating (e.g., a piezoelectric material, such as lithium tantalate or lithium niobate, to form a POI, or “piezoelectric on insulator,” structure).

The aforementioned document also discloses the fact that this type of structure is particularly sensitive to hydrogen, as this atomic species can diffuse and congeal in the trapping layer, which tends to passivate the electrical defects that this layer comprises and, as a result, degrade the structure's RF performance. As documented in the publication “White paper—RF SOI Characterisation” dated January 2015 and published by SOITEC, the RF performance of a substrate can be characterized by a second harmonic distortion measurement.

It was also observed that when the thin film comprised lithium, this atomic species was also likely to diffuse into the structure during the manufacturing stages, freezing in the trapping layer and doping it. As with hydrogen, the presence of lithium in the trapping layer tends to degrade the RF performance of the structure.

To prevent RF performance degradation caused by the diffusion of atomic species (particularly hydrogen) in a structure incorporating a trapping layer, documents WO2021008742 and WO2022023630 propose exploiting the dielectric interlayer to provide a barrier effect.

The nature and dimensions of the various layers making up a structure are not freely chosen. They are generally dictated by the intended application and the characteristics of the components that will be formed using this structure.

For example, and by way of illustration only, the nature and thickness of the dielectric layer of a POI structure are dictated by the expected performance of a surface elastic wave filter formed on the thin piezoelectric layer. The thickness of the trapping layer can also affect the propagation of elastic waves on the surface of the thin layer, and its thickness can also be imposed to ensure the compliant operation of the component.

However, in certain structural configurations, the barrier effect of the dielectric layer proposed in documents WO2021008742 and WO2022023630 may not be sufficient. This is the case, for example, when the structure has a relatively thin trapping layer, for example, less than 0.5 micrometers thick. In such a case, the RF performance of the structure is highly sensitive to species migration in the trapping layer. There are relatively few electric traps in this layer, and a significant proportion of them may be passivated by a small number of trapped species.

When the dielectric interlayer is relatively thin, e.g., less than 200 nm, the diffusion barrier effect of this layer is naturally much less effective, particularly with regard to lithium diffusion in the structure.

In other configurations, the barrier effect of the dielectric layer may impose manufacturing constraints. Thus, when the dielectric interlayer is relatively thick, for example, greater than 20 nm, this layer can introduce stresses into the structure that tend to deform it. An excessively deformed structure can no longer be manipulated and processed by conventional microelectronics equipment, making its manufacture extremely complex, if not impossible.

The solution proposed by documents WO2021008742 and WO2022023630 to guard against the diffusion of atomic species therefore cannot be easily applied to a wide range of dimensions and types of the various layers making up the structure.

### BRIEF SUMMARY

One aim of the present disclosure is to improve this state of the art by providing a structure incorporating a diffusion barrier to certain atomic species, notably hydrogen and/or lithium, in a structure comprising a charge-trapping layer. In particular, one aim of the present disclosure is to provide an interlayer dielectric layer with a diffusion-barrier effect that can be used in a wide range of sizes of the various elements making up the structure.

In order to achieve this aim, the present disclosure proposes a method for manufacturing a structure comprising a thin layer formed from a lithium-based material and transferred onto a support via an interlayer dielectric layer comprising a first dielectric layer, a silicon nitride barrier layer and a second dielectric layer, the support comprising an electric charge-trapping layer arranged superficially, on the thin layer side, on a base substrate. According to the present disclosure, the method comprises the following steps:
forming the first dielectric layer on the trapping layer arranged on a main face of the support;
forming the silicon nitride barrier layer on and in contact with the first dielectric layer and having a thickness of at least 20 nm, between 20% and 30% of a thickness of the dielectric interlayer;
forming the second dielectric layer on and in contact with the barrier layer;
assembling the main face of the support and a main face of a donor substrate to form an intermediate structure;
removing part of the donor substrate from the intermediate structure to define the thin layer on the support.

According to other advantageous non-limiting features of the present disclosure, taken alone or according to any technically feasible combination:
the donor substrate comprises a monocrystalline piezoelectric material;
the donor substrate is provided with a surface dielectric layer on its main face prior to being assembled to the support;
the first dielectric layer and the second dielectric layer are made of silicon oxide or silicon oxynitride;
the first dielectric layer or the second dielectric layer consists of silicon oxynitride incorporating nitrogen in a nitrogen/oxygen ratio of less than 0.5;
the trapping layer is made of polycrystalline silicon;
the formation of the first dielectric layer comprises oxidation of the trapping layer;
the first dielectric layer and the second dielectric layer are made of silicon oxynitride incorporating nitrogen in a variable nitrogen/oxygen ratio increasing in the direction of the barrier layer;
the stack formed by the first dielectric layer, the barrier layer and the second dielectric layer is deposited on the support by “in situ” deposition in a chamber using an LPCVD technique.

According to another aspect, the object of the present disclosure proposes a structure comprising a support formed of an electric charge-trapping layer disposed superficially on a base substrate and comprising a thin layer formed of a lithium-based material and transferred onto the support, the structure comprising an interlayer dielectric layer disposed between and in contact with the support and the thin layer.

According to the present disclosure, t the interlayer dielectric layer comprises:
a. a first dielectric layer disposed on and in contact with the trapping layer;
b. a silicon nitride barrier layer on and in contact with the first dielectric layer and having a thickness of at least 20 nm, between 20% and 30% of a thickness of the dielectric interlayer; and
c. a second dielectric layer on and in contact with the barrier layer.

According to other advantageous non-limiting features of the present disclosure, taken alone or according to any technically feasible combination:
the base substrate is a monocrystalline silicon substrate;
the trapping layer is made of polycrystalline silicon;
the trapping layer is less than 0.5 micrometers thick;
the thin layer consists of a monocrystalline piezoelectric material;
the first dielectric layer and the second dielectric layer consist of silicon oxide or silicon oxynitride;
the first dielectric layer and the second dielectric layer are made of silicon oxynitride incorporating nitrogen in a variable nitrogen/oxygen ratio increasing in the direction of the barrier layer;
the structure is in the form of a circular wafer with a diameter of less than or equal to 200 mm and a curvature of less than 100 micrometers;
the dielectric layer can be less than 200 nm thick;
the barrier layer consists of a non-stoichiometric silicon nitride.

### BRIEF DESCRIPTION OF THE DRAWINGS

Other features and advantages of the present disclosure will emerge from the following detailed description of the present disclosure with reference to the appended figures, in which:

FIG. 1 shows a structure in accordance with the present disclosure;

FIG. 2 shows another structure in accordance with the present disclosure; and

FIG. 3 shows a method for manufacturing a structure in accordance with the present disclosure.

### DETAILED DESCRIPTION

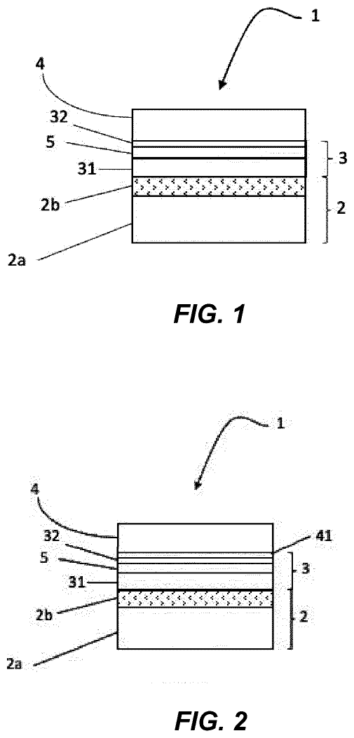

In very general terms and with reference to FIGS. 1 and 2, the present disclosure relates to a structure 1 and a method of manufacturing this structure 1. The structure 1 comprises, in succession, a monocrystalline thin layer 4, an interlayer dielectric layer 3 and a support 2. The support 2 itself comprises a base substrate 2a provided with an electric charge-trapping layer 2b. In the embodiments shown in the figures, the interlayer dielectric layer 3 is in contact with the electric charge-trapping layer 2b and the thin layer 4. As explained in the introduction to the present disclosure, such a structure 1 is particularly suitable for accommodating radio frequency (RF) components on or in the thin layer 4.

Conventionally, the structure 1 can be in the form of a circular wafer, the diameter of which can be 100, 150, 200, 300 or even 450 mm.

The base substrate 2a of the support 2 on which the electric charge-trapping layer 2b rests typically has a thickness of several hundred micrometers. Preferably, the base substrate 2a has a high resistivity, greater than 1000 ohm centimeters, and even more preferably, greater than 2000 ohm centimeters. The density of the charges, holes or electrons, which are likely to move in the base substrate, is thus limited. However, the present disclosure is not limited to a base substrate 2a having such a resistivity, and it also provides RF performance advantages when the base substrate has a more compliant resistivity, on the order of a few hundred ohm centimeters, for example, less than 1000 ohm.cm, or less than 500 ohm.cm or even less than 10 ohm.cm.

For availability and cost reasons, the base substrate 2a preferably consists of monocrystalline silicon. It may be, for example, a CZ silicon substrate with a low interstitial oxygen content between 6 and 10 ppm, or an FZ silicon substrate that has, especially, a naturally very low interstitial oxygen content (below the detection limit usually set at 10¹⁶ cm⁻³). It can also be a CZ silicon substrate having a high amount of interstitial oxygen (designated by the expression “High Oi”) of more than 26 ppm. The base substrate 2a may alternatively be formed from another material: it may, for example, be sapphire, glass, quartz, silicon carbide, etc. In certain circumstances, and, in particular, when the charge-trapping layer 2b is thick enough, for example, more than 30 micrometers thick, the base substrate 2a may have standard resistivity, of less than 1 kohm.cm.

The charge-trapping layer 2b can be quite varied in nature, as recorded in the documents forming the state of the art. In general, it is a non-monocrystalline layer having structural defects such as dislocations, grain boundaries, amorphous zones, interstices, inclusions, pores, etc. These structural defects form traps for the charges liable to circulate in the material, for example, at incomplete or pending chemical bonds. This prevents conduction in the trapping layer, which consequently has high resistivity.

The thickness of the charge-trapping layer 2b, especially when it is formed on a resistive base substrate 2a, may be between 0.1 and 3 μm. However, other thicknesses below or above this range are entirely conceivable, depending on the level of RF performance expected from the structure 1.

Advantageously, and for the sake of simplicity of implementation, this charge-trapping layer 2b is formed of a layer of polycrystalline silicon. It can also comprise layers of, or be formed entirely from, a silicon-carbon alloy. This charge-trapping layer 2b comprising polycrystalline silicon can be formed by deposition on the base substrate 2a.

In an effort to preserve the polycrystalline quality of the charge-trapping layer 2b during heat treatments that can be applied to the structure 1, an amorphous layer, consisting of silicon dioxide, for example, can advantageously be provided on the base substrate 2a before the deposition of the charge-trapping layer 2b.

Alternatively, the charge-trapping layer 2b may be formed by the implantation of a relatively heavy species, such as argon, in a surface thickness of the base substrate 2a, to form therein the structural defects constituting the electric traps. This charge-trapping layer 2b can also be formed by porosification of a surface thickness of the base substrate 2a or by any other method capable of forming structural defects in a surface thickness of the base substrate 2a, with these structural defects being capable of trapping electric charges.

The thin layer 4 of the structure 1 can be of any suitable type, in particular, a monocrystalline material. When the structure 1 is intended to receive integrated semiconductor components, the thin layer 4 can thus be composed of monocrystalline silicon, or of any other monocrystalline semiconductor material such as germanium, silicon germanium, silicon carbide. When the structure 1 is intended to receive surface elastic wave filters, the thin layer 4 can be composed of a monocrystalline piezoelectric and/or ferroelectric material, such as lithium tantalate or lithium niobate. The thin layer 4 can also comprise finished or semi-finished integrated components, initially formed on a donor substrate and transferred onto the support 2 during the step of manufacturing the structure 1. Generally speaking, the thin film can have a thickness of between 10 nm and 10 micrometers, depending on the intended application of the structure 1 and the expected performance of the components.

The interlayer dielectric layer 3 can have a thickness of between 50 nm and several micrometers, for example, 5 micrometers or more.

To prevent the diffusion of certain atomic species toward the charge-trapping layer 2b, the structure 1 comprises a silicon nitride barrier layer 5 in the interlayer dielectric layer 3. “Silicon nitride” refers to a nitride whose general formula is of the SiₓN_{y} form, thus consisting of nitrogen and silicon in proportions that may or may not be stoichiometric (Si₃N₄).

More precisely, the interlayer dielectric layer 3 comprises, formed and arranged on the support 2:
a first dielectric layer 31 disposed on and in contact with the charge-trapping layer 2b;
a silicon nitride barrier layer 5 on and in contact with the first dielectric layer; and
a second dielectric layer 32 on and in contact with the barrier layer 5.

For reasons that will become apparent from the remainder of this disclosure, and as is apparent from FIG. 2, the interlayer dielectric layer 3 may also comprise a surface dielectric layer 41, disposed between the second dielectric layer 32 and the thin layer 4. This surface dielectric layer 41 is advantageously in contact with the thin layer 4 and with the second dielectric layer 32, but this feature is not imperative, and it can be envisaged that the interlayer dielectric layer 3 comprises layers other than the surface dielectric layer 41, arranged between the second dielectric layer 32 and the thin layer 4.

Atomic species liable to diffuse toward the charge-trapping layer 2b may, in particular, come from the thin layer 4. This can be lithium, for example, when the thin layer 4 is made of lithium tantalate or lithium niobate (or, more generally, any lithium-based material). By providing a silicon nitride barrier layer 5 capable of blocking diffusion, inter alia, of lithium between the thin layer 4 and the charge-trapping layer 2b, RF performance degradation of the structure 1 is avoided. For the barrier effect to be effective, particularly with regard to light species such as lithium, it is preferable for the silicon nitride barrier layer 5 to have a thickness of at least 20 nm. In general, it is not necessary to provide a thickness greater than 70 nm for the barrier effect to be sufficient (with regard to the diffusion of light species such as lithium or hydrogen), but a barrier layer 5 may nevertheless be formed with a thickness greater than this 70 nm value if other benefits are expected or if the structure 1 is particularly sensitive to the migration of these species, as will be disclosed in a following section of this disclosure.

The second dielectric layer 32 and, if present, the surface dielectric layer 41, are provided to facilitate assembly of the structure. These layers are advantageously based on silicon oxide, as the adhesive properties of these materials are well known and they can be prepared for assembly (cleaning, activation treatment, etc.). These layers 32, 41 do not need to be thick to fulfill their adhesion function during manufacture of the structure, and advantageously their thicknesses are each between 5 nm and 30 nm.

Finally, the first dielectric layer 31 provides the complementary dielectric thickness to the second dielectric layer 32, the barrier layer 5 and any other dielectric layers arranged on the second dielectric layer 32, to obtain an interlayer dielectric layer 3 of selected thickness. Remember that this dielectric interlayer 3 can have a thickness of between 50 nm and several micrometers, so the first dielectric layer 31 can have a thickness of between 20 nm and several micrometers. This first dielectric layer 31 is preferably based on silicon oxide, for ease of use.

Atomic species likely to migrate to the charge-trapping layer 2b may also come from the interlayer dielectric layer 3 itself, or from the assembly interface present at the second dielectric layer 32. This is particularly the case when the interlayer dielectric layer 3 is produced, at least in part, by deposition techniques involving moderate heat treatments below 650° C. These treatments do not allow certain species, such as hydrogen, to be diffused out of the deposited layer, and these are therefore likely to diffuse toward the charge-trapping layer 2b during the other stages in the manufacture of the structure 1.

To prevent diffusion of these species desorbing from the interlayer dielectric layer 3, in particular, from the first dielectric layer 31 beneath the barrier layer 5, as close as possible to the charge-trapping layer 2b, it may be advantageous to choose the material and technique for forming the first and second dielectric layers 31, 32 (and to a lesser extent, any layers present between the second dielectric layer 32 and the thin layer 4) so that they contain little hydrogen or limit the diffusivity of this hydrogen. This is particularly the case when the interlayer dielectric layer 3 is relatively thick, with a thickness greater than or equal to 200 nm, leading to a first dielectric layer 31 with a thickness typically greater than 100 nm. This is also the case when the charge-trapping layer 2b is relatively thin, less than 500 nm. In both cases, the RF performance of the structure 1 is particularly sensitive to hydrogen diffusion toward the charge-trapping layer 2b, as explained in the introduction to the present disclosure.

Low-hydrogen dielectric layers can be formed by LPCVD (Low Pressure Chemical Vapor Deposition) in the temperature range 650° C. to 850° C., preferably 700° C. to 800° C. In the case of the first dielectric layer 31 disposed directly on the charge-trapping layer 2b, it can be formed by thermal oxidation of this trapping layer, when this layer consists of silicon. To form dielectric layers that limit the diffusivity of this hydrogen, nitrogen can be incorporated (to form a SiON layer). To characterize the proportion of nitrogen in the charge-trapping layer 2b, a measurement of the refractive index of the charge-trapping layer 2b may be used, which varies (at a wavelength of 633 m) between 1.45 for SiO₂ and 2.02 for Si₃N₄ (that is, a stoichiometric silicon nitride).

The proportion of nitrogen in the SiON layer can be freely chosen to limit the expected diffusivity, on the understanding that the higher the proportion, the lower the diffusivity. If it is not desired to excessively modify the acoustic properties of these layers compared with layers formed from silicon oxide (which may affect the performance of certain components formed on structure 1, such as elastic wave components), it is preferable to limit the proportion of nitrogen, for example, so that the nitrogen/oxygen ratio remains between 0.01 and 0.5 or between 0.05 and 0.1.

The proportion of nitrogen in the first dielectric layer 31 and in the second dielectric layer 32 may be the same or different. This proportion may be constant within the layer or vary. In one embodiment, the nitrogen/oxygen ratio is variable in the first dielectric layer 31 and in the second dielectric layer 32, increasing toward the barrier layer 5.

It should be noted that some dielectrics can impart compressive mechanical stress to the substrate on which they are formed. Such is the case with silicon oxide. Other dielectrics, such as silicon nitride, can provide voltage stress. These stresses can lead to deformation of the substrate (“bow”).

Thus, when the first dielectric layer 31 and the second dielectric layer 32 are made of a dielectric material providing compressive mechanical stress, for example, silicon oxide, the thickness of the silicon nitride barrier layer 5 can be adjusted to compensate for this stress. Of course, the thickness of the barrier layer 5 remains above the threshold thickness of 20 nm that gives this layer its barrier effect.

The thickness of the silicon nitride barrier layer 5 is chosen to be between 20% and 30% of the thickness of the interlayer dielectric layer. This is particularly the case when the rest of the interlayer consists of silicon oxide or silicon oxynitride with a nitrogen/oxygen ratio of less than 0.5 and/or when this interlayer 3 has a thickness greater than 100 nm. With such a choice, the deformation of a structure 1 in the form of a circular wafer can be limited, and a diameter greater than or equal to 150 mm, to less than 60 micrometers. For a structure 1 in the form of a circular wafer with a diameter of 200 mm, deformation can be limited to less than 100 micrometers.
Note that this approach to adjusting the thickness of the barrier layer 5 to limit deformation of the structure 1 is particularly useful when the interlayer dielectric layer 3 is relatively thick, in excess of 200 nm. In such a case, the stresses developing in the structure 1 can be relatively high, and it becomes interesting to compensate for them to avoid excessive deformation of the structure. It should also be noted that this deformation is all the greater the larger the size of the structure, for example, the diameter of the wafer when the structure takes the form of a circular wafer.

In other cases, particularly when the interlayer dielectric layer 3 is relatively thin, e.g., less than 200 nm, it may be desirable to limit the stress applied in tension by the silicon nitride barrier layer 5. This can be achieved by forming the barrier layer 5 from a non-stoichiometric nitride, enriched in Si compared to a stoichiometric silicon nitride, so as to reduce its voltage. The index of this type of nitride exceeds 2.02 at 633 nm, tending toward 2.1, 2.2 or even 2.3.

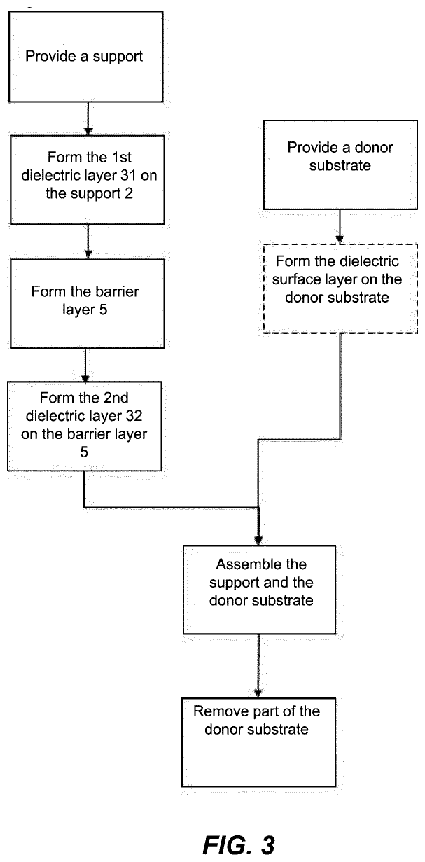

Very generally, and with reference to FIG. 3, the structure 1 can be made by a manufacturing method comprising:
providing a support 2 comprising a superficially arranged electric charge-trapping layer 2b;
forming the first dielectric layer 31 on a “main” face of the support 2;
forming the silicon nitride barrier layer 5 on and in contact with the first dielectric layer 31;
forming the second dielectric layer 32 on and in contact with the silicon nitride barrier layer 5;
assembling the main face of the support and a main face of a donor substrate to form an intermediate structure;
removing part of the donor substrate from the intermediate structure to define the thin layer 4 on the support 2.

In this way, the first dielectric layer 31, the barrier layer 5 and the second dielectric layer 32 are successively applied to the support 2. As previously mentioned, the thickness and/or stoichiometry of the barrier layer 5 can be adjusted to limit deformation of the support 2 after it has received the stack. In this way, the assembly stage is facilitated, since the main faces of the donor substrate and the support are flat, which favors close contact thereof.

“Donor substrate” refers to a substrate made of the material of the thin layer 4, or comprising a surface thickness of this material. For example, the donor substrate can be a monocrystalline silicon bulk substrate, a lithium tantalate or lithium niobate bulk substrate, or a composite substrate consisting of a first substrate on which a layer (at least equal to that of thin layer 4) of lithium tantalate or lithium niobate or other lithium-based materials is applied.

The dielectric layers making up the interlayer dielectric layer 3 can be made by deposition, for example, using LPCVD (“low-pressure chemical vapor deposition”) or PECVD (“plasma-enhanced chemical vapor deposition”) techniques. As already mentioned, the LPCVD technique may be preferable in that it tends to incorporate less hydrogen into the layer formed than the PECVD technique.

The first dielectric layer 31 and/or the second dielectric layer 32 may be made of silicon oxide or silicon oxynitride.

When deposited in silicon oxide or silicon oxynitride, this stack of layers can be produced in situ, in the same deposition equipment and without removing the support from the equipment, which is an interesting possibility from the point of view of production speed.

The use of this “in situ” approach is particularly interesting when the first dielectric layer 31 and the second dielectric layer 32 are made of silicon oxynitride incorporating nitrogen in a variable nitrogen/oxygen ratio increasing in the direction of the silicon nitride barrier layer 5. The incorporation of nitrogen into the equipment can be controlled by varying its concentration as the different layers of the stack are built up.

Alternatively, a first dielectric layer 31 made of silicon oxide can be obtained by oxidizing the charge-trapping layer 2b when the latter is made of silicon. Such a treatment can be implemented by exposing the support 2 provided with the charge-trapping layer 2b in an oxidation furnace to a temperature that is strictly between 700° C. and 1000° C. and in an oxygen-rich atmosphere. This can be a dry or wet atmosphere. As is well-known per se, the duration of this exposure is selected according to the desired thickness of the first dielectric layer. It is generally preferable to limit the oxidation temperature to 900° C. to avoid any risk of recrystallization of the charge-trapping layer 2b. In this approach, oxidation is preferably followed by a polishing step on the oxidized surface to facilitate subsequent assembly of the donor substrate and support substrate 2.

The donor substrate can be provided with a surface dielectric layer 41 on its main face prior to being assembled to the support 2. As already stated, the presence of this surface dielectric layer facilitates the subsequent assembly step between the donor substrate and the second dielectric layer 32 present on the support 2.

The assembly step is advantageously carried out by molecular adhesion. As is well known per se, during a molecular adhesion method, the exposed surfaces of the support 2 (the second dielectric layer) and the donor substrate (possibly formed from the surface dielectric layer), which are perfectly clean, flat and smooth, are brought into close contact with one another to promote the development of molecular bonds, for example, of the van der Waals or covalent type. The two bodies are then assembled without the use of adhesives. These bonds can be strengthened by applying a heat treatment to the intermediate structure.

The step of eliminating part of the donor substrate can be carried out by chemical-mechanical thinning of this substrate. Preferentially, the structure 1 is manufactured by applying Smart Cut™ technology, according to which a layer intended to form the thin layer 4 is delimited by way of an embrittlement plane formed by the implantation of light species (typically hydrogen and/or helium) into the donor substrate. After the assembly step, this layer is removed from the donor substrate by fracture at the embrittlement plane and thus transferred to the support 2.

Whether the removal of part of the donor substrate's thickness is achieved by thinning or fracturing, any type of finishing treatment can be applied to the structure 1 thus formed to conform the thin layer 4 to specifications of thickness, thickness uniformity, roughness or any other type of specification.

Of course, the present disclosure is not limited to the embodiment described and variant embodiments can be added thereto without departing from the scope of the invention as defined by the claims.

1. A method for manufacturing a structure comprising a thin layer formed from a lithium-based material and transferred onto a support via an interlayer dielectric layer comprising a first dielectric layer, a silicon nitride barrier layer and a second dielectric layer, the support comprising an electric charge-trapping layer arranged superficially, on the thin layer side, on a base substrate, the method comprising
forming the first dielectric layer on the electric charge-trapping layer arranged on a main face of the support;
forming the silicon nitride barrier layer on and in contact with the first dielectric layer and having a thickness of at least 20 nm, between 20% and 30% of a thickness of the interlayer dielectric layer;
forming the second dielectric layer on and in contact with the silicon nitride barrier layer;
assembling the main face of the support and a main face of a donor substrate to form an intermediate structure; and
removing part of the donor substrate from the intermediate structure to define the thin layer on the support.

2. The method of claim 1, wherein the donor substrate comprises a monocrystalline piezoelectric material.

3. The method of claim 1, wherein the electric charge-trapping layer comprises polycrystalline silicon.

4. The method of claim 1, further comprising forming a surface dielectric layer on a main face of the donor substrate prior to the assembling of the main face of the support and the main face of the donor substrate.

5. The method of claim 1, wherein the first dielectric layer and the second dielectric layer comprise silicon oxide or silicon oxynitride.

6. The method of claim 5, wherein the first dielectric layer and the second dielectric layer comprise silicon oxynitride incorporating nitrogen in a variable nitrogen/oxygen ratio increasing in a direction of the silicon nitride barrier layer.

7. The method of claim 5, wherein a stack formed by the first dielectric layer, the silicon nitride barrier layer and the second dielectric layer is deposited in situ on the support in a chamber using LPCVD.

8. The method of claim 1, wherein the forming of the first dielectric layer comprises oxidation of the charge-trapping layer.

9. A structure, comprising: a support including an electric charge-trapping layer on a base substrate, a thin layer of a lithium-based material on the support, and an interlayer dielectric layer disposed between and in contact with the support and the thin layer, the interlayer dielectric layer including:
a first dielectric layer disposed on and in contact with the electric charge-trapping layer;
a silicon nitride barrier layer on and in contact with the first dielectric layer and having a thickness of at least 20 nm, between 20% and 30% of a thickness of the interlayer dielectric layer; and
a second dielectric layer on and in contact with the silicon nitride barrier layer.

10. The structure of claim 9, wherein the electric charge-trapping layer comprises polycrystalline silicon.

11. The structure of claim 9, wherein the electric charge-trapping layer has a thickness of less than 0.5 micrometers.

12. The structure of claim 9, wherein the thin layer comprises a monocrystalline piezoelectric material.

13. The structure of claim 9, wherein the first dielectric layer and the second dielectric layer comprise silicon oxide or silicon oxynitride.

14. The structure of claim 9, wherein the first dielectric layer and the second dielectric layer comprise silicon oxynitride incorporating nitrogen in a variable nitrogen/oxygen ratio increasing in a direction extending toward the silicon nitride barrier layer.

15. The structure of claim 9, wherein the structure is a circular wafer with a diameter of less than or equal to 200 mm and a curvature of less than 100 micrometers.

16. The structure of claim 9, wherein the interlayer dielectric layer has a thickness of greater than 200 nm.

17. The structure of claim 9, wherein the silicon nitride barrier layer comprises a non-stoichiometric silicon nitride.
